(19) United States
(12) Patent Application Publication
(10) Pub. No.: US 2026/0146839 A1
(43) Pub. Date: May 28, 2026

(54) SENSOR FOR DETECTING A POSITION OF A MECHANICAL COMPONENT WITHIN A POLAR SPHERICAL COORDINATE REFERENCE SYSTEM

(71) Applicant: Gefran S.p.A., Provaglio d'Iseo (IT)

(72) Inventors: Davide Alghisi, Provaglio d'Iseo (IT); Michele Vaccaro, Provaglio d'Iseo (IT); Marco Svara, Provaglio d'Iseo (IT)

(73) Assignee: Gefran S.p.A., Provaglio d'Iseo, BS (IT)

(21) Appl. No.: 19/122,173

(22) PCT Filed: Oct. 17, 2023
(86) PCT No.: PCT/IB2023/060466

§ 371 Date: Apr. 17, 2025

(30) Foreign Application Priority Data
Oct. 20, 2022 (IT) 102022000021657

(51) Int. Cl. G01B 7/008; G01B 7/02; G01D 5/165; G01D 5/20; G01P 7/00; G01P 15/14; G01P 15/18; G01R 33/032; G01R 33/09

(52) U.S. Cl. CPC G01B 7/008; G01B 7/023; G01D 5/165; G01D 5/2066; G01P 7/00; G01P 15/14; G01P 15/18; G01R 33/0327; G01R 33/09

(57) ABSTRACT

A sensor for detecting a position of a mechanical component within a polar spherical coordinate reference system, comprising, accommodated inside a sensor body of the sensor: a linear position sensor configured to detect a first linear coordinate of a position of a free end of a slider in the polar spherical coordinate reference system; an acceleration sensor; an angular speed sensor; a data processing unit configured to: determine a second colatitude coordinate and a third longitude coordinate of said position based on acceleration values and angular speed values detectable by said sensors; store in a memory unit a plurality of sets of three detected polar spherical coordinates representative of a path travelled by the free end of the slider in said reference system.

### FIELD OF THE INVENTION

The present invention relates to sensors employable for detecting movement between mechanical components, in particular to a sensor for detecting a position of a mechanical component within a polar spherical coordinate reference system.

### TECHNOLOGICAL BACKGROUND OF THE INVENTION

Detecting the movement between mechanical components, such as the mechanical components of an articulated arm of an excavator, is a very important aspect of automation which allows accurately monitoring the reliability of such a movement during the service life of the mechanical components and therefore being able to intervene with maintenance and/or replacement activities in order to ensure an adequate performance as well as safety level.

Nowadays, such a detection is obtainable with the employment of linear, self-supporting position sensors with a cylindrical body, which are widespread in the world of automation.

They generally consist of a single-stage telescopic structure formed by a movable slider which slides with respect to a body of the sensor, which represents a fixed part.

The free end of the movable slider is connected to a mechanical component the position of which is to be monitored, while the free end of the sensor body represents the origin of the measurement reference system.

The position measurement produced by such a linear sensor is a function of the linear distance between the slider and the body of the sensor.

Indeed, the movement of the mechanical component generates an extension or compression of the telescopic structure, with a consequent variation in distance between movable slider and sensor body.

An apparent limitation of the aforesaid linear position sensor is that it is capable of producing only the linear position measurement because is transduces the cylindrical body which can extend and compress in a single direction in space.

In order to overcome such a limitation, a mechanical component could be equipped with multiple linear position sensors which could ensure, as a whole, sturdiness, reliability and accuracy of the measurements produced.

However, a solution based on multiple independent sensors located on the same mechanical component would be bulky, costly, complex and not always implementable from a practical viewpoint.

### SUMMARY

It is the object of the present invention to devise and provide a sensor for detecting a position of a mechanical component within a polar spherical coordinate reference system which allows at least partially overcoming the drawbacks mentioned above with reference to the prior art and which is small in size, affordably manufacturable, and greatly versatile as for the possible implementations for which it could be intended.

Such an object is achieved by a sensor according to claim 1.

The present invention relates to a method for detecting a position of a mechanical component within a polar spherical coordinate reference system.

### BRIEF DESCRIPTION OF THE DRAWINGS

Further features and advantages of the sensor according to the invention will become apparent from the following description of preferred embodiments thereof, given by way of non-limiting indication, with reference to the accompanying drawings, in which:

FIG. 1 diagrammatically shows a sensor for detecting a position of a mechanical component within a polar spherical coordinate reference system according to an embodiment of the present invention;

FIG. 2 diagrammatically shows, by means of a block diagram, a sensor for detecting a position of a mechanical component within a polar spherical coordinate reference system according to the present invention;

FIG. 3 shows a longitudinal section view of the sensor in FIG. 1 for the purpose of illustrating the detection principle of a first linear position coordinate in a polar spherical coordinate reference system;

FIGS. 4a and 4b show the side views of the sensor in FIG. 1 for the purpose of illustrating the detection principle of a second colatitude coordinate in a polar spherical coordinate reference system;

FIGS. 5a and 5b show top views of the sensor in FIG. 1 for the purpose of illustrating the detection principle of a third longitude coordinate in a polar spherical coordinate reference system;

FIGS. 6a and 6b show an example of use of the sensor in FIG. 1;

FIGS. 7a-7f show further examples of use of the sensor in FIG. 1;

FIG. 8 diagrammatically shows a path travelled by a point of a mechanical component in a polar spherical coordinate reference system;

FIG. 9 diagrammatically shows a sensor for detecting a position of a mechanical component within a polar spherical coordinate reference system according to a further embodiment of the present invention;

FIGS. 10, 11a, 11b and 12 show, by means of respective block diagrams, components of the sensor of the present invention, when employed to perform an action recognition method.

### DETAILED DESCRIPTION

With reference to the aforesaid drawings, a sensor 1 for detecting a position of a mechanical component within a polar spherical coordinate reference system S1 is now described.

“Mechanical component” means any mechanical component employed in the industrial field the position of which requires to be measured and monitored during the movement thereof, for example, in the movable hydraulic field, a segment of an articulated arm of a material-handling machine, components of suspensions or power steering, components of agricultural means and tracked earthmoving machines, components of plastic molding machines, components of mold support carriages, extractors or rollers.

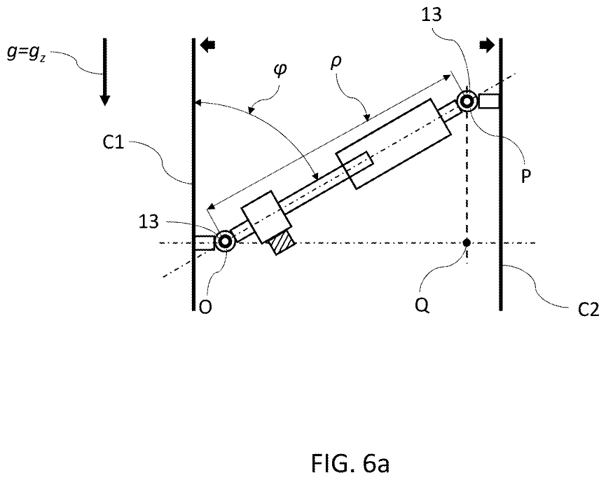

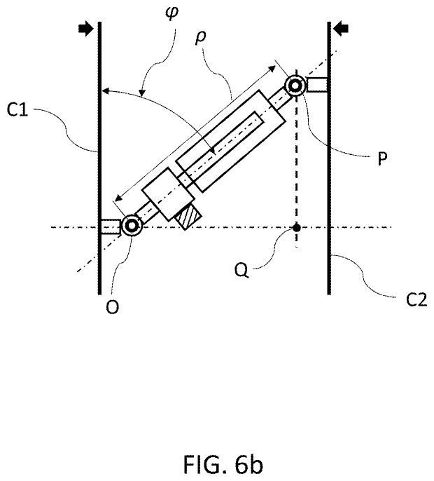

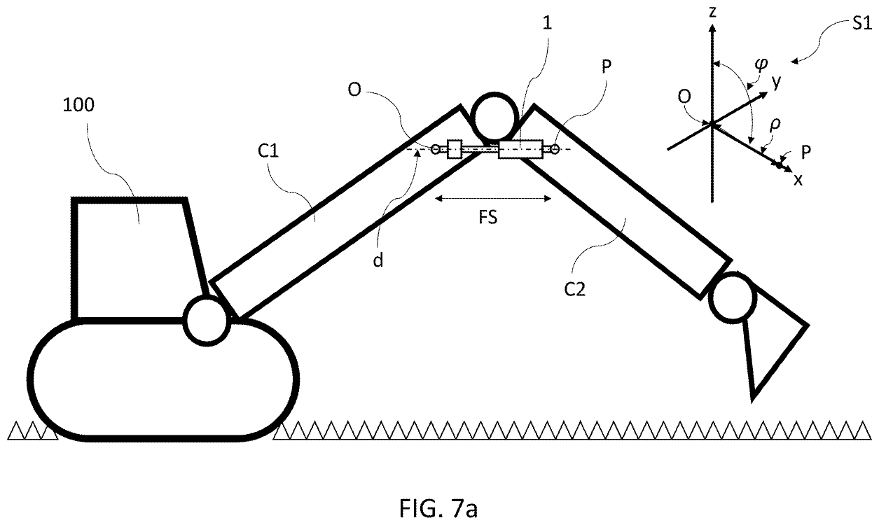

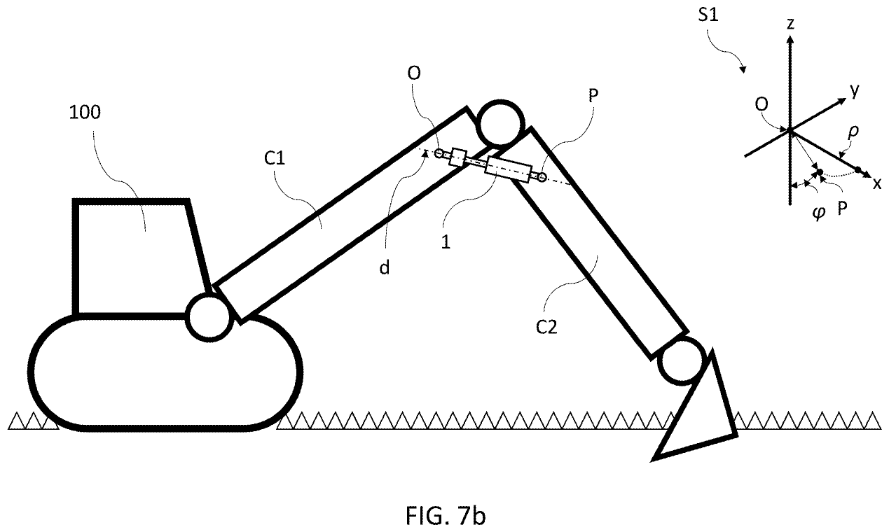

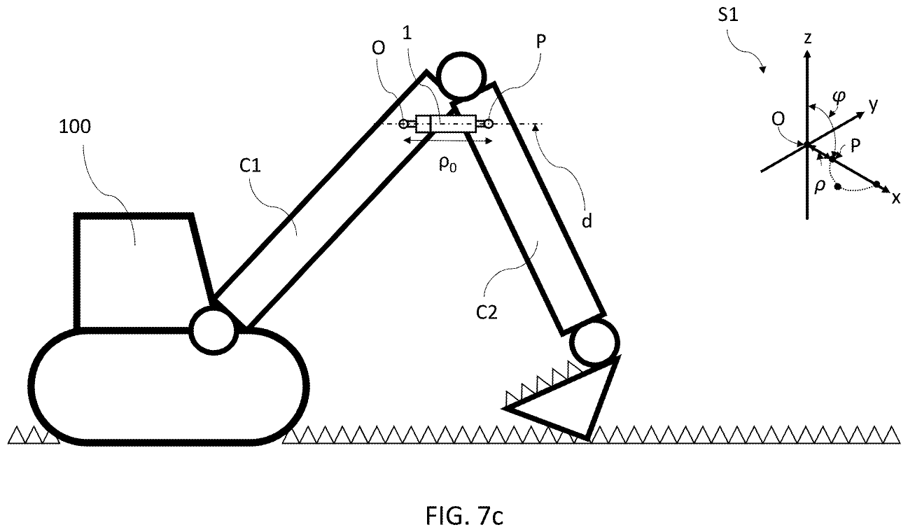

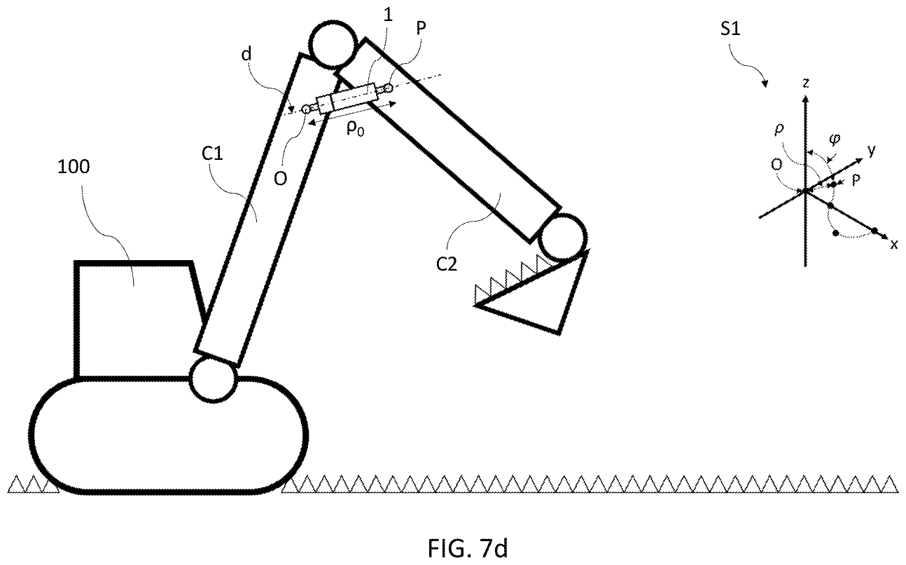

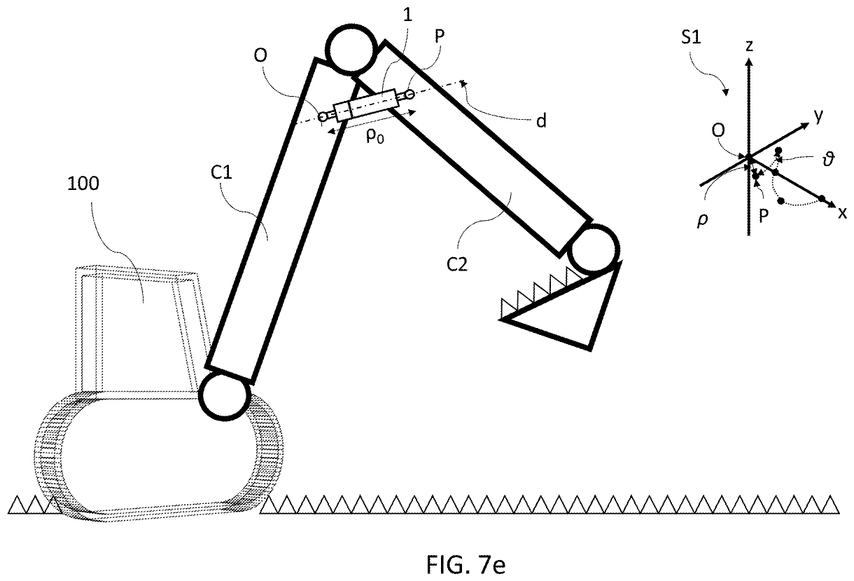

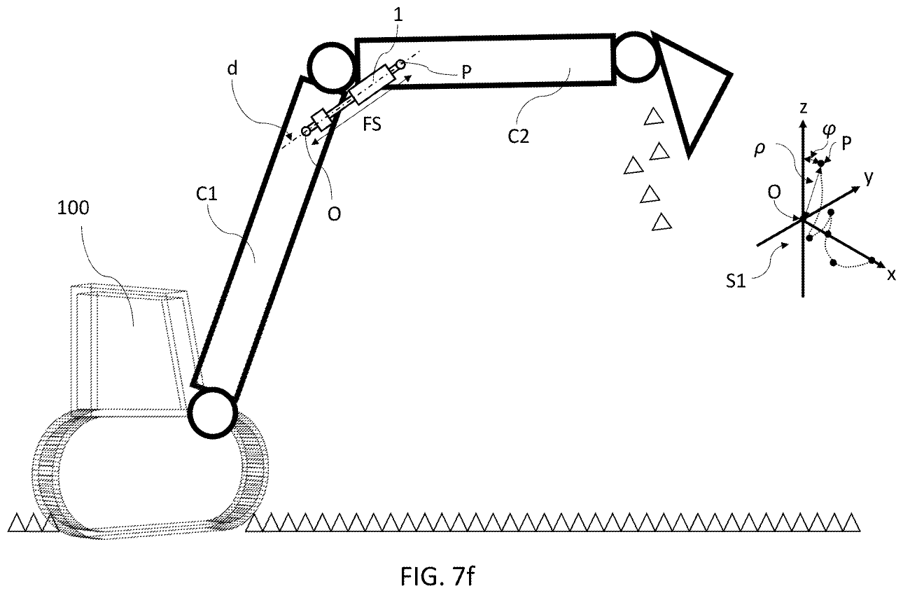

By way of example, the mechanical component in FIGS. 6a and 6b is a wall (C1 or C2), while the mechanical component in FIGS. 7a-7f is a segment (C1 or C2) of an articulated excavator arm.

Returning in general to the sensor 1 according to the present invention, it comprises a sensor body 4 extending along a longitudinal development axis d, the latter shown in the drawings with a dashed line.

The sensor body 4 has a respective free end O configured to be operatively connected to a first mechanical component C1 (shown in FIGS. 6a, 6b, 7a-7f, for example).

The free end O of the sensor body 4 represents the origin of a polar spherical coordinate reference system S1.

The sensor 1 comprises a slider 2 operatively connected to the sensor body 4 so as to be able to slide, with respect to the sensor body 4, coaxially along the longitudinal development axis d of the sensor body 4.

The slider 2 has a respective free end P configured to be operatively connected to a second mechanical component C2 (it also shown, for example, in FIGS. 6a, 6b, 7a-7f).

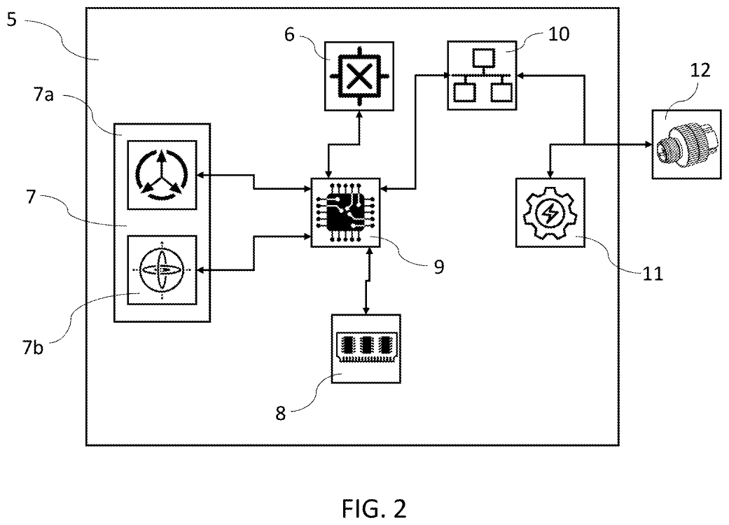

With particular reference to FIG. 2, the sensor 1 further comprises a data processing unit 9 accommodated inside the sensor body 4.

The data processing unit 9 is, for example, a microcontroller, a microprocessor or a programmable logic device such as an FPGA (Field Programmable Gate Array).

Moreover, the sensor 1 comprises a memory unit 8 operatively associated with the data processing unit 9.

The memory unit 8 is accommodated inside the sensor body 4.

The memory unit 8 is a rewritable and permanent type of memory and is based on EEPROM, FRAM or MRAM technology, for example.

In greater detail, as diagrammatically shown in FIG. 2, it should be noted that the data processing unit 9 and the memory unit 8 are preferably mounted on an electronic board 5 (diagrammatically shown in the drawings, where seen) accommodated inside the sensor body 4.

The sensor 1 further comprises a linear position sensor 6, 3 accommodated inside the sensor body 4 and operatively connected to the data processing unit 9.

The linear position sensor 6, 3 is configured to detect a first linear coordinate position p of a position of the free end P of the slider 2 in the polar spherical coordinate reference system S1.

The sensor 1 further comprises an acceleration sensor 7, 7a accommodated inside the sensor body 4 and operatively connected to the data processing unit 9.

The data processing unit 9 is configured to determine a second colatitude coordinate φ of the position of the free end P of the slider 2 in the polar spherical coordinate reference system S1 based on acceleration values to which the sensor body 4 is subject, which are detectable by the acceleration sensor 7, 7a.

In greater detail, as diagrammatically shown in FIG. 2, it should be noted that the acceleration sensor 7, 7a is also preferably mounted on the electronic board 5 accommodated inside the sensor body 4.

The sensor 1 further comprises an angular speed sensor 7, 7b accommodated inside the sensor body 4 and operatively connected to the data processing unit 9.

The data processing unit 9 is configured to determine a third longitude coordinate ϑ of the position of the free end P of the slider 2 in the polar spherical coordinate reference system S1 based on angular speed values to which the sensor body 4 is subject, which are detectable by the angular speed sensor 7, 7b.

In greater detail, as diagrammatically shown in FIG. 2, it should be noted that the angular speed sensor 7, 7b is also preferably mounted on the electronic board 5 accommodated inside the sensor body 4.

According to the present invention, the data processing unit 9 is configured to store, in the memory unit 8, a plurality of sets of three detected polar spherical coordinates.

Each set of three polar spherical coordinates comprises the first linear coordinate ρ, the second colatitude coordinate φ and the third longitude coordinate ϑ of the position of the free end P of the slider 2 in the polar spherical coordinate reference system S1 detected in an instant of time tᵢ, with 1<i<N of a plurality of successive instants of time t₁, t₂, . . . , tᵢ, . . . t_{N}.

The plurality of sets of three stored in the memory unit is representative of a path PS travelled by the free end P of the slider 2 in the polar spherical coordinate reference system S1.

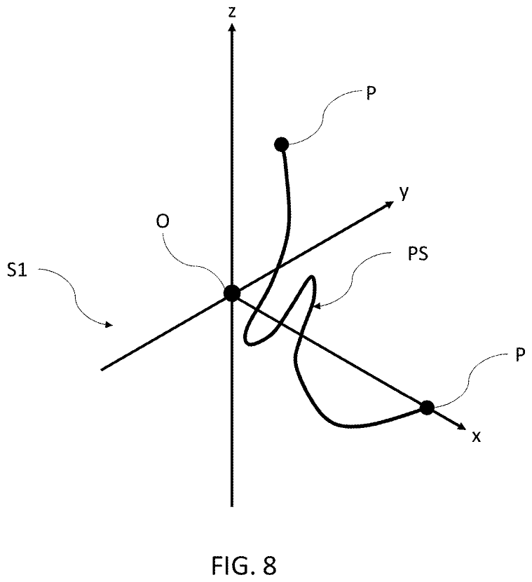

An example of path PS is diagrammatically shown in FIG. 8.

According to an embodiment shown in the drawings, the linear position sensor 6, 3 comprises a sensible element 6 arranged on the sensor body 4 and an electric or magnetic element 3 arranged on the slider 2.

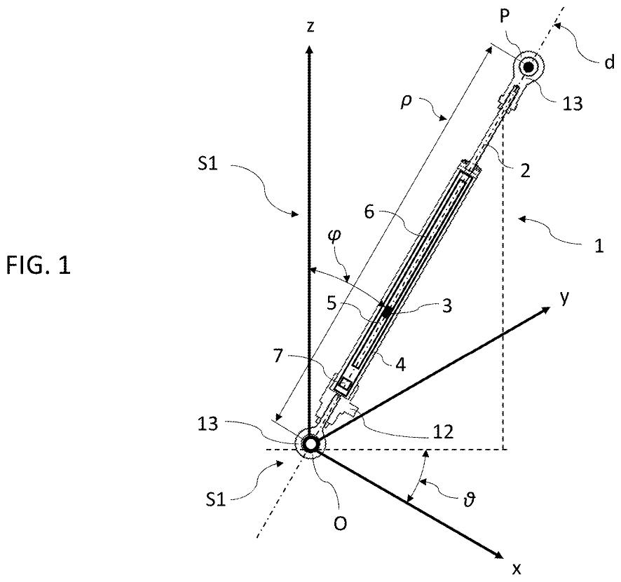

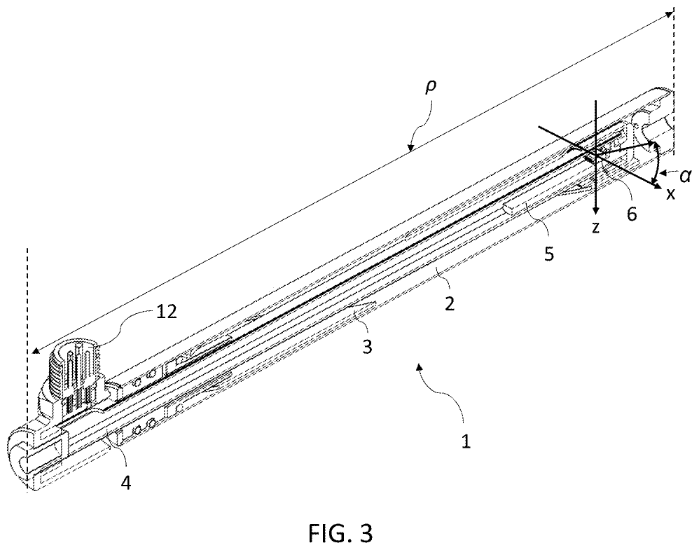

According to an embodiment, in combination with the preceding one and shown in FIGS. 1 and 3, the sensible element 6 is a resistive track extending along the sensor body 4 along the longitudinal development axis d and the electric or magnetic element 3 is at least one sliding contact.

In this embodiment, the first linear coordinate p of the position of the free end P of the slider 2 in the polar spherical coordinate reference system S1, i.e., the mutual position of the slider 2 with respect to the sensor body 4 (carrier radius) is a function of a resistive value of the resistive track measurable between an end of the resistive track and the position of the at least one sliding contact on the resistive track.

It should be noted that in this embodiment, the principle applied by the linear position sensor 6, 3 for detecting the first linear coordinate ρ of the position of the free end P of the slider 2 in the polar spherical coordinate reference system S1 is a potentiometric-type principle.

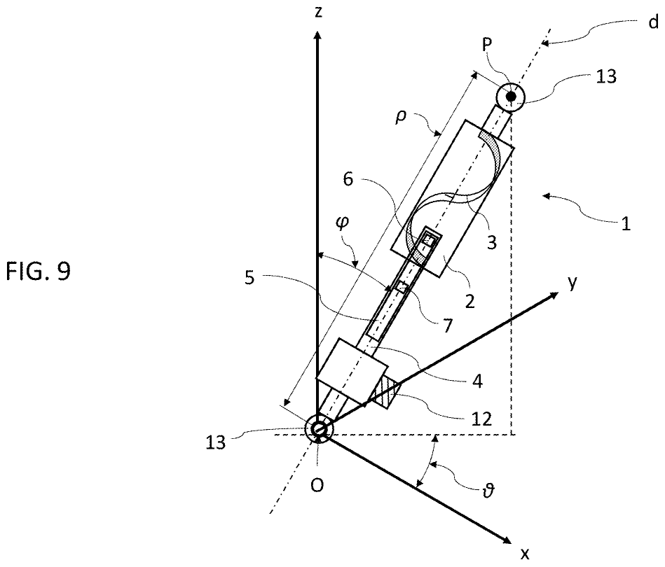

According to a further embodiment, alternative to the preceding one and shown in FIG. 9, the sensible element 6 is a magnetic field sensor arranged in the sensor body 4 so that respective mutually orthogonal sensible axes are in turn orthogonal to the longitudinal development axis d.

In this embodiment, the electric or magnetic element 3 is a cylindrical magnetic helix wound around the slider 2 along the longitudinal development axis d.

In this embodiment, the first linear coordinate of the position of the free end P of the slider 2 in the polar spherical coordinate reference system S1 is a function of a magnetic field orientation generatable by the cylindrical magnetic helix according to a cylindrical helix development.

In greater detail, the magnetic field sensor is preferably arranged on the electronic board 5 accommodated inside the sensor body 4 so as to have the respective mutually orthogonal sensible axes, which in turn are orthogonal to the longitudinal development axis d, so as to be able to measure an angular orientation a of the magnetic field generated by the cylindrical magnetic helix.

The angular orientation measurement α detected by the magnetic field sensor varies at most in the range of values 0°-360°, with the extreme of the range not included because coincident with value 0°.

Therefore, the magnetic field sensor represents a detection sensor of absolute angular orientation on a single revolution.

By way of example, assuming that:
the cylindrical magnetic helix has a constant pitch;
the measurement α is detected and provided by the magnetic field sensor in an increasing manner with respect to the extension of the slider 2 with respect to the sensor body 4;
at a resting position po of the sensor 1 (completely compressed), the magnetic field sensor provides an angular orientation value α>0°;
at a bottom-scale position FS of the sensor 1 (completely extracted), the magnetic field sensor provides an angular orientation value α≈360°;
the free end O of the sensor body 4, connected to a first mechanical component C1, represents the origin of the polar spherical coordinate reference system S1,
the free end P of the slider 2 is connected to a second mechanical component C2;
it is possible to relate the mutual position of the slider 2 with respect to the sensor body 4, i.e. the first linear coordinate p of the position of the free end P of the slider 2 in the polar spherical coordinate reference system S1, also referred to as carrier radius, with the measurement of the angular orientation value α of the magnetic field generated by the cylindrical magnetic helix according to the development of a cylindrical helix, as indicated by the following mathematical relationship:

$$ρ = \frac{α}{360} \cdot FS + {ρ}_{0} \qquad ( 1 )$$

According to further embodiments, the sensible element 6 is a magnetic field sensor made from a Hall effect integrated circuit, or giant magnetoresistive or tunnel.

According to further embodiments, the sensible element 6 of the linear position sensor 6, 3 can be a wire of magnetostrictive material and the electric or magnetic element 3 of the linear position sensor 6, 3 can be a magnet.

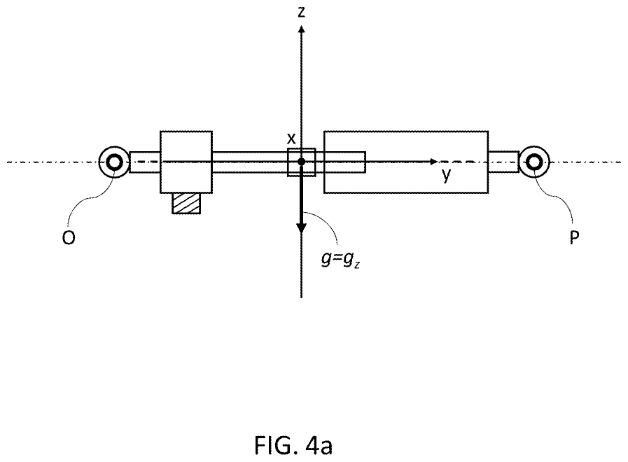

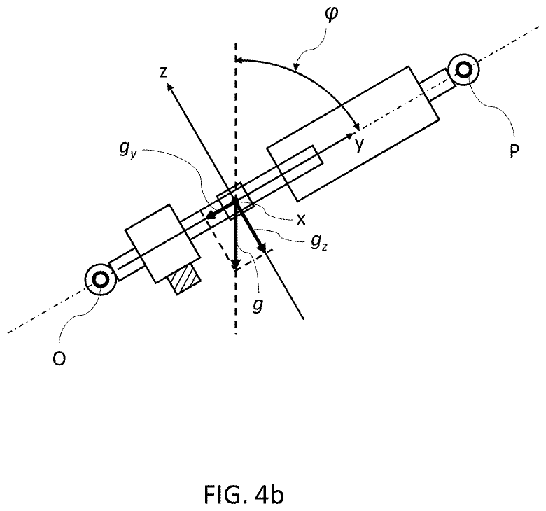

According to an embodiment, in combination with any one of those described above, shown in FIGS. 2, 4a and 4b, the acceleration sensor 7, 7a comprises at least one accelerometer 7a with a respective set of three mutually orthogonal sensible axes x, y, z (shown in FIGS. 4a and 4b).

The at least one accelerometer 7b is in MEMS technology, for example.

The second colatitude coordinate φ of the position of the free end P of the slider 2 in the polar spherical coordinate reference system S1 is a function of acceleration values to which the sensor body 4 is subject, which are detectable by the at least one accelerometer 7a along each of the sensible axes x, y, z of the respective set of three sensible axes.

With particular reference to FIGS. 4a and 4b, the second colatitude coordinate φ of the position of the free end P of the slider 2 in the polar spherical coordinate reference system S1 is represented by the inclination of the plane on which the sensible axes x and y of the set of three sensible axes of the at least one accelerometer 7a lie with respect to the gravity acceleration direction g.

For example, in this embodiment, the second colatitude coordinate φ can be, for example, calculated with the following mathematical relationship:

$$φ = atan ( \frac{\sqrt{{g}_{x}^{2} + {g}_{z}^{2}}}{{g}_{y}} ) \qquad ( 2 )$$

where:
gₓ is the projection of the gravity acceleration g along the sensible axis x of the at least one accelerometer 7a;
g_{y} is the projection of the gravity acceleration g along the sensible axis y of the at least one accelerometer 7a;
g_{z} is the projection of the gravity acceleration g along the sensible axis z of the at least one accelerometer 7a.

According to a further embodiment, in combination with the preceding one, the angular speed sensor 7, 7b comprises at least one gyroscope 7b with a respective set of three mutually orthogonal sensible axes x, y, z.

The data processing unit 9 is configured to determine the second colatitude coordinate φ of the position of the free end P of the slider 2 in the polar spherical coordinate reference system S1 as a function of acceleration values to which the sensor body 4 is subject, which are detectable by the at least one accelerometer 7a along each of the sensible axes x, y, z of the respective set of three sensible axes and angular speed values detectable by the at least one gyroscope 7b along each of the sensible axes x, y, z of the respective set of three sensible axes.

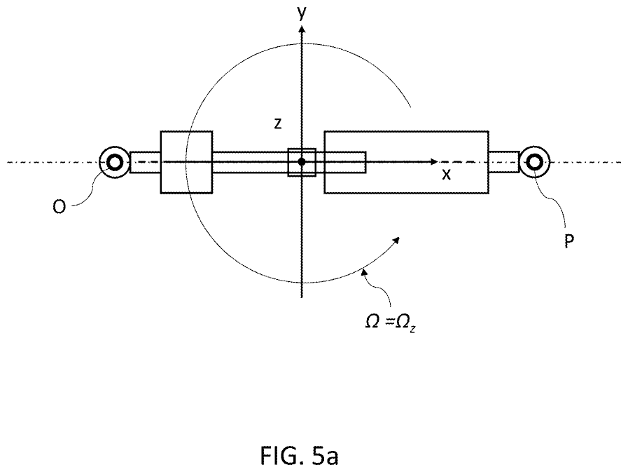

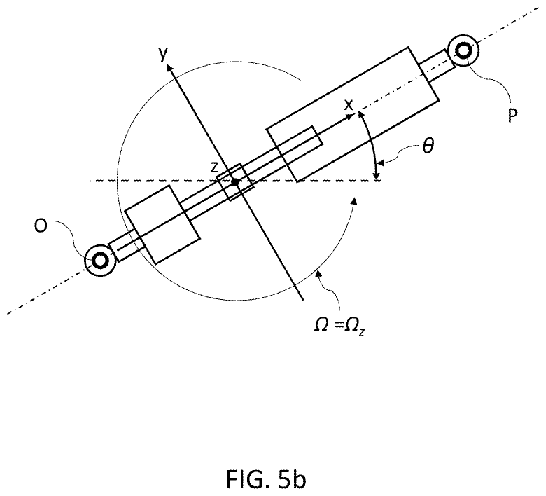

According to a further embodiment, in combination with any one of the preceding ones, shown in FIGS. 2, 5a and 5b, the angular speed sensor 7, 7b comprises at least one gyroscope 7b with a respective set of three mutually orthogonal sensible axes x, y, z.

The data processing unit 9 is configured to determine the third longitude coordinate 9 of the position of the free end P of the slider 2 in the polar spherical coordinate reference system S1 as a function of angular speed values to which the sensor body 4 is subject, which are detectable by the at least one gyroscope 7b along each of the sensible axes of the respective set of three sensible axes, and of an initial inclination value of the longitudinal development axis d with respect to the set of three sensible axes of the at least one gyroscope 7b.

In particular, the inclination of the longitudinal development axis d with respect to the initial inclination value to, with respect to the set of three sensible axes of the at least one gyroscope 7b, occurs on a plane on which the sensible axes x, y of the set of three sensible axes x, y, z of the at least one gyroscope 7b lie.

The third longitude coordinate ϑ of the position of the free end P of the slider 2 in the polar spherical coordinate reference system S1 can be, for example, calculated by means of an integration in time of the angular speed Q to which the sensor body 4 is subject with respect to an initial inclination value ϑ₀, employing the following mathematical relationship:

$$ϑ = \int Ω \cdot dt + {ϑ}_{0} \qquad ( 3 )$$

in which the angular speed Ω is determined by the data processing unit 9 as a combination of the components Ωₓ, Ω_{y} and Ω_{z} thereof, i.e., the projections of the angular speed Ω along the respective sensible axes x, y, z of the set of three sensible axes of the at least one gyroscope 7.

According to an embodiment, in combination with any one of the preceding ones and shown in the drawings, the respective free end O of the sensor body 4 comprises a self-aligning joint.

According to an embodiment, in combination with any one of the preceding ones and shown in the drawings, the respective free end P of the slider 2 comprises a self-aligning joint.

According to an embodiment, in combination with any one of those described above, shown in FIG. 2, the sensor 1 further comprises a bus communication module 10 operatively connected to the data processing unit 9 which allows the exchange of electrical signals between the data processing unit 9 and the field bus used in the control system of the mechanical components to which the sensor 1 is connected.

According to an embodiment, in combination with the preceding one, shown in the drawings, the sensor 1 further comprises a connector 12 adapted to provide the electrical connection (electrical supply voltage and electrical signals) to the field bus used in the control system of the mechanical components to which the sensor 1 is connected.

The connector 12 is also operatively connected to the data processing unit 9 by means of the bus communication module 10.

In an embodiment, in combination with the preceding one, shown in FIG. 2, the sensor 1 further comprises an electrical supply management module 11 operatively connected to the connector 12, adapted to generate the levels of electrical voltage required for the operation of the electronic devices accommodated inside the sensor body 4 starting from the electrical supply voltage supplied to the field bus.

Also referring now to FIGS. 6a and 6b, the first mechanical component C1 comprises a first surface and the second mechanical component C2 comprises a second surface.

The first surface and the second surface face each other.

In an embodiment, in combination with any one of those described above, the data processing unit 9 is configured to determine a real distance OP between the first surface and the second surface based on the first linear coordinate ρ and the second colatitude coordinate φ of the position of the free end P of the slider 2 in the polar spherical coordinate reference system S1 belonging to a detected set of three polar spherical coordinates.

For example, the real distance OP between the first surface and the second surface is determinable, by the data processing unit 9, by employing the following mathematical relationship:

$$\overline{OP} = ρ \cdot sin ( φ ) \qquad ( 4 )$$

Moreover, according to an embodiment, in combination with the preceding one, the data processing unit 9 is configured to determine a misalignment between the free end P of the slider and the free end O of the sensor body 4 based on the first linear coordinate ρ and the second colatitude coordinate φ of the position of the free end P of the slider 2 in the polar spherical coordinate reference system S1 belonging to a detected set of three polar spherical coordinates.

The determination of a misalignment advantageously allows obtaining an indication on the sensor 1 being properly or not properly installed between the first surface and the second surface.

For example, a misalignment between the free end P of the slider and the free end O of the sensor body 4 is determinable, by the data processing unit 9, by means of employing the following mathematical relationship:

$$\overline{PO} = ρ \cdot cos ( φ ) \qquad ( 5 )$$

Therefore, the misalignment error made during the installation of the sensor 1 is of non-linear type, increasing with the cosine of the second colatitude coordinate φ.

According to an embodiment, according to any one of those described above, the path PS travelled by the free end P of the slider 2 in the polar spherical coordinate reference system S1 represented by a plurality of sets of three stored in the memory unit 8 is representative of a set action carried out by the first mechanical component C1 and the second mechanical component C2 and employable as reference recognition model in a recognition algorithm of movement models.

Indeed, the recognition of actions carried out by mechanical components can be carried out with different methods, including the use of raw data in the set of three polar spherical coordinates ρ, φ and ϑ measured in an set time instant tᵢ, 1<i<N, N being integer, as input, and the extraction of different features which can be used as input for the implementable recognition method.

By analyzing the evolution of the individual sets of three polar spherical coordinates produced by the sensor 1 of the present invention, indeed it is possible to identify unique combinations which describe the performance of a particular action carried out by mechanical components.

With reference to FIGS. 7a-7f, reference is made below to an articulated arm C1, C2 of an excavator 100.

For example, assuming that the articulated arm of the excavator shown in FIG. 7a is in the initial condition thereof in plane XZ of the polar spherical coordinate reference system S1, an action of extending the articulated arm C1, C2 is uniquely defined when:
the first linear coordinate ρ is close to the maximum extension FS;
the second colatitude coordinate φ is almost orthogonal to the horizontal (for the frequency of the function atan=90°;
the third longitude coordinate ϑ is equal to zero because it is assumed that the initial condition is of movement in the plane XZ of the polar spherical coordinate reference system S1.

A bucket standing action in the material loading area shown in FIG. 7b is uniquely defined when:
the first linear coordinate ρ has decreasing trend;
the second colatitude coordinate φ has exceeded a discontinuity of periodicity of the function atan and has increasing negative value;
the third longitude coordinate ϑ is equal to zero because it is assumed that the initial condition is of movement in the plane XZ of the polar spherical coordinate reference system S1.

A material loading action shown in FIG. 7c is uniquely defined when:
the first linear coordinate ρ is close to the minimum extension ρ₀;
the second colatitude coordinate φ has become horizontal again, around the point of discontinuity +/−90°;
the third longitude coordinate ϑ is equal to zero because it is assumed that the initial condition is of movement in the plane XZ of the polar spherical coordinate reference system S1.

A loading bucket raising action shown in FIG. 7d is uniquely defined when:
the first linear coordinate ρ is close to the minimum extension ρ₀;
the second colatitude coordinate φ has exceeded a discontinuity of periodicity of the function atan and has decreasing positive value;
the third longitude coordinate ϑ is equal to zero because it is assumed that the initial condition is of movement in the plane XZ of the polar spherical coordinate reference system S1.
A rotation action towards the material unloading area shown in FIG. 7e is uniquely defined when:
the first linear coordinate ρ is close to the minimum extension ρ₀;
the second colatitude coordinate φ has exceeded a discontinuity of periodicity of the function atan and has decreasing positive value;
the third longitude coordinate ϑ has increasing positive value.

A material unloading action shown in FIG. 7f is uniquely defined when:
the first linear coordinate ρ is close to the maximum extension FS;
the second colatitude coordinate φ has exceeded a discontinuity of periodicity of the function atan and has decreasing positive value;
the third longitude coordinate ϑ has increasing positive value.

Thus, the excavating activity is therefore formed by a sequence of actions, to which correspond specific movements that the measurer performs in space by tracing a characteristic path PS, an example of which is shown in FIG. 8.

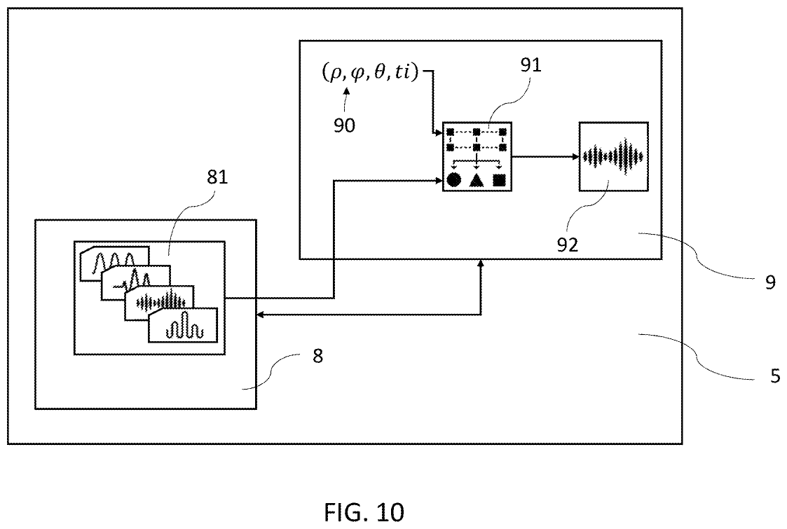

According to the present invention, according to an embodiment shown in FIG. 10, an action recognition method executable by the data processing unit 9 of the sensor 1 is now described.

Such a method implements a movement model recognition concept (Motion Pattern Recognition), known per se.

According to the method, the polar spherical coordinates ρ, φ and ϑ referring to instant tᵢ are input 90 provided to a recognition algorithm 91 which is capable of discriminating the corresponding action in that precise moment with an excellent degree of accuracy.

The recognition algorithm 91 is, for example, a pattern matching algorithm or a neural network, for example, of the RNN (Recurrent Neural Network) type.

Pattern matching is a form of model recognition in which the data are represented as series of carriers of features and/or parameters referred to as models, shown in FIG. 10 by reference numeral 81.

Each action (model 81) is stored in the memory unit 8 as a separate model.

The inputs 90 are organized in models 81 stored before performing the recognition process.

At the start of the recognition process, an input 90 is compared with the models 81 stored in the memory unit 8 (as shown in FIG. 10).

The stored model 81 corresponding the most to the model corresponding to the input 90 is identified as action and it is said selected model 92 which will be the best match for input 90.

Model matching is performed at path level associated with the movement of the mechanical components.

The matching process involves a frame-by-frame comparison of the spectral models and generates an overall similarity assessment for each model.

It is not necessary for the comparison to produce an identical match to establish an overall similarity because the single actions, and therefore the movement of a same mechanical component, are affected by the surrounding environment.

This variation can be due to a series of factors, among which the different speed with which the action is performed, or the different orientation of the axes of the reference system.

Whatever the cause of the variation between the stored models 81 and the input 90, it is necessary for there to be a way for minimizing the time differences between the models so that the quickest or slowest actions of the same movement are not identified as different movements.

In this respect, it is known in literature that the minimization process of the time differences is referred to as time alignment.

The approach most commonly used for performing the time alignment in model matching is a pattern matching technique referred to as Dynamic Time Warping (DTW).

Most model matching systems have a predetermined acceptability threshold.

The function thereof is that of avoiding the noise and situations not included in the stored models 81 from being erroneously identified as acceptable inputs.

If no model matching exceeds the acceptability threshold, no recognition is registered.

Model matching is highly effective with short and distinct actions and it is necessary for there to be at least all the models capable of representing the almost totality of the actions.

Alternatively to pattern matching algorithms, it is possible to use recurrent neural networks (RNN), which are a type of neural network specialized in the use of sequential data or time series.

As all neural networks, recurrent neural networks also use training data to learn.

They stand out for their “memory” because they take information from preceding inputs to affect the current input and output.

In this respect, while traditional networks presume the inputs and outputs are independent from one another, the output of recurrent neural networks depends on the elements preceding the sequence.

By way of example, it should be considered a sequence of a determined movement.

For it to make sense, such a sequence must be expressed in a specific order.

Consequently, recurrent neural networks must consider the form and use this information to predict the successive action in the sequence.

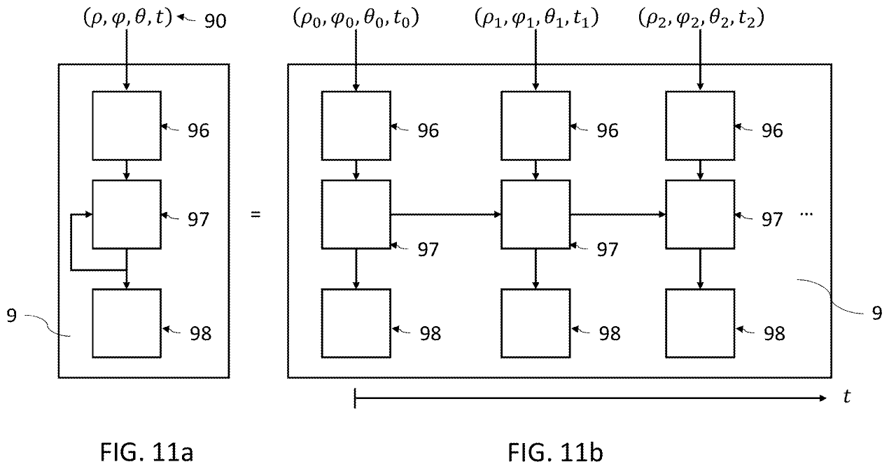

With reference to the graph shown in FIG. 11a, the rolled view of the recurrent neural network RNN, comprising nodes 96, 97 and 98, represents the entire neural network, which in the case of the proposed sensor, represents the entire predicted action for the mechanical component described by a determined sequence of input 90.

The unrolled view, shown in FIG. 11b, instead shows the single layers, or time phases, of the recurrent neural network.

Each layer, comprising nodes 96, 97 and 98, corresponds to a single piece of information of the sequence in a given time instant tᵢ, therefore to the single variable ρ, o Φ o ϑ.

The inputs at the preceding time instants are shown as a hidden state in the third phase to predict the output of the action taking place or the successive sequence.

Another distinctive feature of recurrent neural networks is the sharing of the parameters in each layer of the network.

As with a pattern matching algorithm, a training path for creating a reference dataset is also provided for recurrent neural network RNN training.

In this respect, the stored models 81 are learned by the sensor 1 during a dedicated training session.

The learned models are registered in the memory unit 8 in the step referred to as enrollment and will constitute the reference dataset for a pattern matching algorithm.

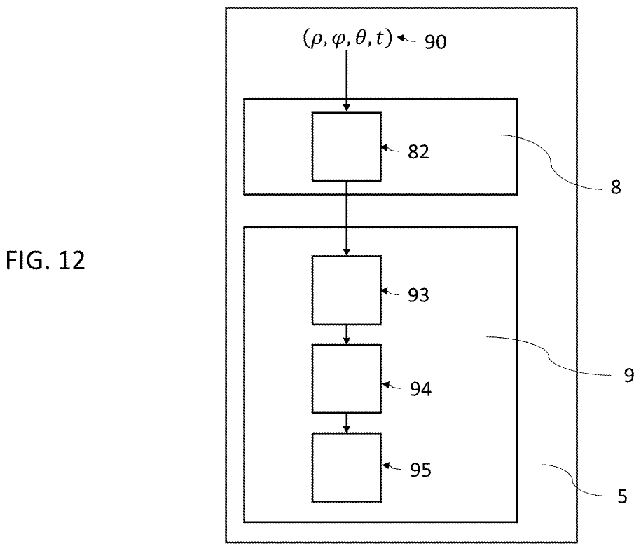

A general architecture of the training step is shown in FIG. 12.

The of the analysis action performed autonomously by the data processing unit 9 of the sensor 1 also enables the identification of “how” the action is performed.

In this case, the subject being studied is the identification of a particular faulty condition.

In order to implement this functionality, it is sufficient to also enter, in the reference dataset of stored models 81, registrations related to the faulty conditions to be identified.

Once identified, the data processing unit 9 of the sensor 1 can suggest maintenance activities based on prescribed interventions for each cause.

A method of detecting a position of a mechanical component within a polar spherical coordinate reference system S1 is now described.

The method comprises a step of providing a sensor body 4 extending along a longitudinal development axis d. The sensor body 4 has a respective free end O configured to be operatively connected to a first mechanical component. The free end O of the sensor body 4 represents the origin of the polar spherical coordinate reference system S1.

The method further comprises step of providing a slider 2 operatively connected to the sensor body 4 so as to be able to slide, with respect to the sensor body 4, coaxially along the longitudinal development axis d of the sensor body 4. The slider 2 has a respective free end P configured to be operatively connected to a second mechanical component C2.

The method further comprises a step of providing a data processing unit 9 accommodated inside the sensor body 4.

The method further comprises a step of providing a memory unit 8 operatively associated with the data processing unit 9. The memory unit 8 is accommodated inside the sensor body 4.

The method further comprises a step of providing a linear sensor 6, 3 accommodated inside the sensor body 4 and operatively connected to the data processing unit 9.

The method further comprises a step of providing an acceleration sensor 7, 7a accommodated inside the sensor body 4 and operatively connected to the data processing unit 9.

The method further comprises a step of providing an angular speed sensor 7, 7b accommodated inside the sensor body 4 and operatively connected to the data processing unit 9.

The method, for each instant of time tᵢ, 1<i<N, N being integer, of a plurality of successive instants of time t₁, t₂, . . . , tᵢ, . . . , t_{N}, comprises steps of:
detecting, by said linear sensor 6, 3, a first linear coordinate ρ of a position of the free end P of the slider 2 in the polar spherical coordinate reference system S1;
determining, by the data processing unit 9, a second colatitude coordinate φ of the position of the free end P of the slider 2 in the polar spherical coordinate reference system S1 based on acceleration values to which the sensor body 4 is subject, which are detected by the acceleration sensor 7, 7a;
determining, by the data processing unit 9, a third longitude coordinate ϑ of the position of the free end P of the slider 2 in the polar spherical coordinate reference system S1 based on angular speed values to which the sensor body 4 is subject, which are detected by said angular speed sensor 7, 7b;
storing, in the memory unit 8, by the data processing unit 9, a set of three polar spherical coordinates comprising the first linear coordinate ρ, the second colatitude coordinate φ and the third longitude coordinate ϑ of the position of the free end P.
A plurality of sets of three polar spherical coordinates stored in the memory unit 8 is representative of a path PS travelled by the free end P of the slider 2 in the polar spherical coordinate reference system S1.

As shown, the object of the present invention is fully achieved because the sensor just described has several advantages.

The self-supporting position sensor of the present invention with cylindrical body, consisting of a movable slider, the end of which is connected to a first mechanical component, and a fixed sensor body, the free end of which represents the origin of the polar spherical coordinate reference system, can be defined as multi-variable because it comprises multiple sensible elements adapted to measure both linear movements and the rotation and inclination with respect to the horizontal.

A specific data processing unit included in the sensor body combines the linear movement, rotation and inclination measurements to determine the polar spherical coordinates identifying the position of the first mechanical component within the polar spherical coordinate reference system.

The time evolution of the polar spherical coordinates is registered in a specific memory unit always included in the sensor body and represents a path travelled by the first mechanical component during the measuring.

From a metrological viewpoint, the sensor is advantageously autonomous in compensating for any residual misalignments of the installation step which can compromise the accuracy of the position measurement.

From a functional viewpoint, by analyzing the path travelled by the mechanical component being measured, the sensor is autonomous in recognizing the actions performed by the mechanical component, comparing them with stored models of actions learned previously in a training step.

In addition, being in fact of the stand-alone type, the sensor of the present invention certainly improves the disadvantages of the background art concerning poor resolution, bulkiness, cost and complexity.

Indeed, the sensor of the present invention is a contact sensor, self-supporting, has a cylindrical body and comprises therein the possibility of producing simultaneously and storing several types of position measurement (linear, angular, inclination).

Moreover, the sensor of the present invention complies with the requirements of a position sensor, which are:
maximum measurement range of the extension of an articulated arm of the order of a meter;
low cost;
sturdiness, to resist extreme temperatures from −40° C. up to +85° C., thermal and mechanical shock up to 50 g, vibrations, corrosion and solar radiation;
increased levels of reliability according to functional safety standards.

In order to meet contingent needs, those skilled in the art may make changes and adaptations to the above-described embodiments of the sensor, and replace elements with others which are functionally equivalent, without departing from the scope of the following claims.

Each of the features described above as belonging to one possible embodiment can be implemented irrespective of the other embodiments described.

1. A sensor for detecting a position of a mechanical component within a polar spherical coordinate reference system, comprising:
a sensor body extending along a longitudinal development axis, said sensor body having a respective free end configured to be operatively connected to a first mechanical component, the free end of the sensor body representing the origin of the polar spherical coordinate reference system;
a slider operatively connected to the sensor body so as to slide, with respect to the sensor body, coaxially along the longitudinal development axis of the sensor body, said slider having a respective free end configured to be operatively connected to a second mechanical component;
the sensor further comprising:
a data processing unit accommodated inside the sensor body;
a memory unit operatively associated with the data processing unit, the memory unit being accommodated inside the sensor body;
a linear position sensor accommodated inside the sensor body and operatively connected to the data processing unit, said linear sensor being configured to detect a first linear coordinate of a position of the free end of the slider in the polar spherical coordinate reference system;
an acceleration sensor accommodated inside the sensor body and operatively connected to the data processing unit, the data processing unit being configured to determine a second colatitude coordinate of the position of the free end of the slider in the polar spherical coordinate reference system based on acceleration values to which the sensor body is subject, which are detectable by the acceleration sensor;
an angular speed sensor accommodated inside the sensor body and operatively connected to the data processing unit, the data processing unit being configured to determine a third longitude coordinate of the position of the free end of the slider in the polar spherical coordinate reference system based on angular speed values to which the sensor body is subject, which are detectable by said angular speed sensor,
the data processing unit being configured to store, in the memory unit, a plurality of sets of three detected polar spherical coordinates, each set of three polar spherical coordinates comprising the first linear coordinate, the second colatitude coordinate and the third longitude coordinate of the position of the free end of the slider in the polar spherical coordinate reference system detected in an instant of time tᵢ, 1<i<N, N being integer, of a plurality of successive instants of time t₁, t₂, . . . , tᵢ, . . . , t_{N},
the plurality of sets of three stored in the memory unit being representative of a path travelled by the free end of the slider in the polar spherical coordinate reference system.

2. The sensor according to claim 1, wherein the linear position sensor comprises a sensible element arranged on the sensor body and an electric or magnetic element arranged on the slider.

3. The sensor according to claim 2, wherein the sensible element is a resistive track extending along the sensor body along the longitudinal development axis and the electric or magnetic element is at least one sliding contact, the first linear coordinate of the position of the free end of the slider in the polar spherical coordinate reference system being a function of a resistive value of the resistive track measurable between one end of the resistive track and the position of the at least one sliding contact on the resistive track.

4. The sensor according to claim 2, wherein the sensible element is a magnetic field sensor arranged in the sensor body so that respective mutually orthogonal sensible axes in turn are orthogonal to the longitudinal development axis, and the electric or magnetic element is a cylindrical magnetic helix wound around the slider along the longitudinal development axis, the first linear coordinate of the position of the free end of the slider in the polar spherical coordinate reference system being in function of a magnetic field orientation generatable by the cylindrical magnetic helix according to a cylindrical helix development.

5. The sensor according to claim 4, wherein the sensible element is a magnetic field sensor made from a Hall effect integrated circuit, or giant magnetoresistive or tunnel.

6. The sensor according to claim 2, wherein the sensible element is a wire of magnetostrictive material and the electric or magnetic element (3) is a magnet.

7. The sensor according to claim 1, wherein the acceleration sensor comprises at least one accelerometer with a respective set of three mutually orthogonal sensible axes x, y, z, the second colatitude coordinate of the position of the free end of the slider in the polar spherical coordinate reference system being in function of acceleration values to which the sensor body is subject, which are detectable by the at least one accelerometer along each of the sensible axes x, y, z of the respective set of three sensible axes.

8. The sensor according to claim 7, wherein the angular speed sensor comprises at least one gyroscope with a respective set of three mutually orthogonal sensible axes x, y, z, the data processing unit being configured to determine the second colatitude coordinate of the position of the free end of the slider in the polar spherical coordinate reference system as a function of the acceleration values to which the sensor body is subject, which are detectable by the at least one accelerometer along each of the sensible axes x, y, z of the respective set of three sensible axes, and of angular speed values to which the sensor body is subject, which are detectable by the at least one gyroscope along each of the set of three sensible axes x, y, z of the respective set of three sensible axes.

9. The sensor according to claim 1, wherein the angular speed sensor comprises at least one gyroscope with a respective set of three mutually orthogonal sensible axes x, y, z, the data processing unit being configured to determine the third longitude coordinate of the position of the free end of the slider in the polar spherical coordinate reference system in function of angular speed values to which the sensor body is subject, which are detectable by the at least one gyroscope along each of the set of three sensible axes of the respective set of three sensible axes, and of an initial inclination value of the longitudinal development axis with respect to the set of three sensible axes of the at least one gyroscope.

10. The sensor according to claim 1, wherein the respective free end of the sensor body comprises a self-aligning joint.

11. The sensor according to claim 1, wherein the respective free end of the slider comprises a self-aligning joint.

12. The sensor according to claim 1, wherein the first mechanical component comprises a first surface and the second mechanical component comprises a second surface, the first surface and the second surface facing each other,
the data processing unit being configured to determine a real distance (OP) between the first surface and the second surface based on the first linear coordinate and the second colatitude coordinate of the position of the free end of the slider in the polar spherical coordinate reference system belonging to a detected set of three polar spherical coordinates.

13. The sensor according to claim 12, wherein the data processing unit is configured to determine a misalignment between the free end of the slider and the free end of the sensor body based on the first linear coordinate and the second colatitude coordinate of the position of the free end of the slider in the polar spherical coordinate reference system belonging to a detected set of three polar spherical coordinates.

14. The sensor according to claim 1, wherein the path travelled by the free end of the slider in the polar spherical coordinate reference system represented by a plurality of sets of three stored in the memory unit is representative of a set action carried out by the element employable as recognition model in a recognition algorithm of movement models.

15. A method of detecting a position of a mechanical component within a polar spherical coordinate reference system, comprising steps of:
providing a sensor body extending along a longitudinal development axis, said sensor body having a respective free end configured to be operatively connected to a first mechanical component, the free end of the sensor body representing the origin of the polar spherical coordinate reference system;
providing a slider operatively connected to the sensor body so as to slide, with respect to the sensor body, coaxially along the longitudinal development axis of the sensor body, said slider having a respective free end configured to be operatively connected to a second mechanical component;
providing a data processing unit accommodated inside the sensor body;
providing a memory unit operatively associated with the data processing unit, the memory unit being accommodated inside the sensor body;
providing a linear sensor accommodated inside the sensor body and operatively connected to the data processing unit;
providing an acceleration sensor accommodated inside the sensor body and operatively connected to the data processing unit;
providing an angular speed sensor accommodated inside the sensor body and operatively connected to the data processing unit;
for each instant of time tᵢ, 1<i<N, N being integer, of a plurality of successive instants of time t₁, t₂, . . . , t_{N}:
detecting, by said linear sensor, a first linear coordinate of a position of the free end of the slider in the polar spherical coordinate reference system;
determining, by the data processing unit, a second colatitude coordinate of the position of the free end of the slider in the polar spherical coordinate reference system based on acceleration values to which the sensor body is subject, which are detected by the acceleration sensor;
determining, by the data processing unit, a third longitude coordinate of the position of the free end of the slider in the polar spherical coordinate reference system based on angular speed values to which the sensor body is subject, which are detected by said angular speed sensor;
storing, in the memory unit, by the data processing unit, a set of three polar spherical coordinates comprising the first linear coordinate, the second colatitude coordinate and the third longitude coordinate of the position of the free end;
a plurality of sets of three polar spherical coordinates stored in the memory unit being representative of a path travelled by the free end of the slider in the polar spherical coordinate reference system.
